(19) United States
(12) Patent Application Publication
(10) Pub. No.: US 2025/0047251 A1
(43) Pub. Date: Feb. 6, 2025

(54) OPERATIONAL AMPLIFIER WITH LOW NOISE AND WIDE OUTPUT SWING

(71) Applicant: STMicroelectronics International N.V., Geneva (CH)

(72) Inventors: Luv PANDEY, Aligarh (IN); Aashish AGRAWAL, Noida (IN)

(21) Appl. No.: 18/775,758

(22) Filed: Jul. 17, 2024

Related U.S. Application Data
(60) Provisional application No. 63/516,713, filed on Jul. 31, 2023.

(51) Int. Cl. H03F 3/45

(52) U.S. Cl. CPC H03F 3/45269; H03F 2200/294

(57) ABSTRACT

Various examples in accordance with the present disclosure provide an operational amplifier with low noise and wide output swing.

### CROSS REFERENCE TO RELATED APPLICATIONS

This application claims priority to U.S. Provisional Patent Application No. 63/516,713 filed on Jul. 31, 2023, which is incorporated herein by reference in its entirety.

### FIELD OF THE INVENTION

Example embodiments of the present disclosure relate generally to operational amplifier and, more particularly, low noise inverter-based amplifier with wide output swing.

### BACKGROUND

Applicant has identified many technical challenges and difficulties associated with operational amplifiers. Through applied effort, ingenuity, and innovation, Applicant has solved many of these identified problems by developing the embodiments of the present disclosure, which are described in detail below.

### BRIEF SUMMARY

Various embodiments described herein related to an operational amplifier with low noise and wide output swing is provided.

In accordance with one aspect of the present disclosure, an operational amplifier is provided. In some embodiments, the operational amplifier comprises an input stage. The input stage comprises a first inverter and a second inverter coupled together and configured to operate in a differential fashion; a first common-tail transistor selectively coupled to the first inverter and the second inverter via a first switch, the first common-tail transistor configured to define a biasing current; and a second common-tail transistor selectively coupled to the first inverter and the second inverter via a second switch. The operational amplifier further comprises an output stage. The output stage comprises a third inverter and a fourth inverter coupled together, the third inverter and the fourth inverter selectively coupled to a supply voltage via a third switch and selectively coupled to a ground via a fourth switch; a first capacitive coupling configured to couple the third inverter to a first output of the input stage; and a second capacitive coupling configured to couple the fourth inverter to a second output of the input stage.

In some embodiments, the first inverter comprises a first PMOS transistor and a first NMOS transistor coupled together via a drain terminal of the first PMOS transistor and a drain terminal of the first NMOS transistor; and the second inverter comprises a second PMOS transistor and a second NMOS transistor coupled together via a drain terminal of the second PMOS transistor and a drain terminal of the second NMOS transistor.

In some embodiments, the first PMOS transistor and the second PMOS transistor are coupled together via a source terminal of the first PMOS transistor and a source terminal of the second PMOS transistor; and the first NMOS transistor and the second NMOS transistor are coupled together via a source terminal of the first NMOS transistor and a source terminal of the second NMOS transistor.

In some embodiments, the third inverter comprises a third PMOS transistor and a third NMOS transistor coupled together via a drain terminal of the third PMOS transistor and a drain terminal of the third NMOS transistor; and the fourth inverter comprises a fourth PMOS transistor and a fourth NMOS transistor coupled together via a drain terminal of the fourth PMOS transistor and a drain terminal of the fourth NMOS transistor.

In some embodiments, the third PMOS transistor and the fourth PMOS transistor are coupled together via a source terminal of the third PMOS transistor and a source terminal of the fourth PMOS transistor; and the third NMOS transistor and the fourth NMOS transistor are coupled together via a source terminal of the third NMOS transistor and a source terminal of the fourth NMOS transistor.

In some embodiments, a gate terminal of the third PMOS transistor and a gate terminal of the third NMOS transistor are coupled to the first output of the input stage via the first capacitive coupling; and a gate terminal of the fourth PMOS transistor and a gate terminal of the fourth NMOS transistor are coupled to the second output of the input stage via the second capacitive coupling.

In some embodiments, the first capacitive coupling comprises a first switched-capacitor circuit.

In some embodiments, the second capacitive coupling comprises a second switched-capacitor circuit.

In some embodiments, the operational amplifier further comprises a biasing current circuit coupled to the first common-tail transistor.

In some embodiments, further comprises a common-mode feedback circuit coupled to the second common-tail transistor.

In some embodiments, the operational amplifier is configured to operate in one or more of a biasing phase and an amplification phase.

In some embodiments, in the biasing phase, each of the first switch, the second switch, the third switch, and the fourth switch are in an opened state.

In accordance with another aspect of the present disclosure, an operational amplifier is provided. In some embodiments, the operational amplifier comprises an input stage. The input stage comprises a first inverter and a second inverter coupled together and configured to operate in a differential fashion; a first common-tail transistor coupled to the first inverter and the second inverter, the first common-tail transistor configured to define a biasing current; and a second common-tail transistor coupled to the first inverter and the second inverter. The operational amplifier further comprises an output stage. The output stage comprises a third inverter and a fourth inverter coupled together; a first capacitive coupling configured to couple the third inverter to a first output of the input stage; and a second capacitive coupling configured to couple the fourth inverter to a second output of the input stage.

In some embodiments, the first inverter comprises a first PMOS transistor and a first NMOS transistor coupled together via a drain terminal of the first PMOS transistor and a drain terminal of the first NMOS transistor; and the second inverter comprises a second PMOS transistor and a second NMOS transistor coupled together via a drain terminal of the second PMOS transistor and a drain terminal of the second NMOS transistor.

In some embodiments, the first PMOS transistor and the second PMOS transistor are coupled together via a source terminal of the first PMOS transistor and a source terminal of the second PMOS transistor; and the first NMOS transistor and the second NMOS transistor are coupled together via a source terminal of the first NMOS transistor and a source terminal of the second NMOS transistor.

In some embodiments, the third inverter comprises a third PMOS transistor and a third NMOS transistor coupled together via a drain terminal of the third PMOS transistor and a drain terminal of the third NMOS transistor; and the fourth inverter comprises a fourth PMOS transistor and a fourth NMOS transistor coupled together via a drain terminal of the fourth PMOS transistor and a drain terminal of the fourth NMOS transistor.

In some embodiments, the third PMOS transistor and the fourth PMOS transistor are coupled together via a source terminal of the third PMOS transistor and a source terminal of the fourth PMOS transistor; and the third NMOS transistor and the fourth NMOS transistor are coupled together via a source terminal of the third NMOS transistor and a source terminal of the fourth NMOS transistor.

In some embodiments, a gate terminal of the third PMOS transistor and a gate terminal of the third NMOS transistor are coupled to the first output of the input stage via the first capacitive coupling; and a gate terminal of the fourth PMOS transistor and a gate terminal of the fourth NMOS transistor are coupled to the second output of the input stage via the second capacitive coupling.

In some embodiments, the operational amplifier further comprises a biasing current circuit coupled to the first common-tail transistor.

In some embodiments, the operational amplifier further comprises a common-mode feedback circuit coupled to the second common-tail transistor.

The foregoing illustrative summary, as well as other exemplary objectives and/or advantages of the disclosure, and the manner in which the same are accomplished, are further explained in the following detailed description and its accompanying drawings.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 provides an example multiplying digital-to-analog converter (MDAC) of a pipelined digital-to-analog converter (ADC) in which an operational amplifier may be used.

FIG. 2 illustrates an example operational amplifier in accordance with at least one embodiment of the present disclosure.

FIG. 3 provides a flowchart depicting operations of an example operational amplifier in a biasing phase in accordance with at least one example embodiment of the present disclosure.

FIG. 4A provides a flowchart depicting operations of an example operational amplifier in an amplification phase in accordance with at least one example embodiment of the present disclosure.

FIG. 4B provides an example timing diagram corresponding to a bias phase and an amplification phase in accordance with at least one example embodiment of the present disclosure.

FIG. 5 illustrates an example operational amplifier in accordance with at least one embodiment of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

As used herein, the term “or” is used in both the alternative and conjunctive sense, unless otherwise indicated. The terms “illustrative” and “example” are used to be examples with no indication of quality level. Terms such as “computing,” “determining,” “generating,” and/or similar words are used herein interchangeably to refer to the creation, modification, or identification of data. Further, “based on,” “based on in part on,” “based at least on,” “based upon,” and/or similar words are used herein interchangeably in an open-ended manner such that they do not indicate being based only on or based solely on the referenced element or elements unless so indicated. Like numbers refer to like elements throughout.

In some examples, an operational amplifier may refer to an electronic component that increases the amplitude or strength of an input signal, for example, without altering its original shape or characteristics. As described above, there are many technical challenges and difficulties associated with operational amplifiers. For example, many applications, such as high speed analog-to digital converters (ADC), require operational amplifiers with a high bandwidth and a high gain. However, to satisfy such high bandwidth and high gain requirements, the operational amplifier may consume a large amount of power. As another example, the amount of current consumed may vary significantly across process, voltage, and temperature (PVT), which in turn can result in large variation with respect to other parameters (e.g., gain, bandwidth, noise, and/or other parameters) associated with an operational amplifier. As yet another example, to satisfy high bandwidth and high gain requirements, a large amount of sample noise voltage variance (e.g., KT/C noise) may be generated, which may negatively impact the overall noise performance of the operational amplifier.

Embodiments of the present disclosure address the above mentioned challenges and difficulties, as well as other challenges and difficulties associated with operational amplifiers. Specifically, embodiments of the present disclosure provide an operational amplifier with low noise and wide output swing that can satisfy the high bandwidth and high gain requirements associated with many applications utilizing an operational amplifier. Moreover, embodiments of the present disclosure provide for mitigating the amount of power consumed. Some embodiments, include two amplifier stages, with the first amplifier stage (e.g., input stage) comprising a current-biased inverter amplifier, and a second amplifier stage (e.g., output stage) comprising a capacitively-biased inverter amplifier. In some embodiments, the current-biased inverter amplifier includes inverter(s) comprising PMOS and NMOS transistors. In some embodiments, the capacitively-biased inverter amplifier comprises inverter(s) comprising PMOS and NMOS transistors. In some embodiments, the PMOS and NMOS transistors of the first amplifier stage and/or the PMOS and NMOS transistors of the second amplifier stage are configured as drivers. For example, some embodiments utilize the respective PMOS and NMOS transistors of the first amplifier stage to drive the second amplifier stage and/or a load. Some embodiments, utilize a common-tail transistor at the first amplifier stage to define the biasing current for the operational amplifier.

By utilizing a current-biased inverter amplifier (e.g., with a common-tail transistor) at the first amplifier stage and a capacitively-biased inverter amplifier at the second amplifier stage, embodiments of the present disclosure avoids any KT/C noise at the input of first amplifier stage, and mitigates/reduces the impact of KT/C noise generated at the input of second amplifier stage. In this regard, embodiments of the present disclosure improves the overall noise performance of the operational amplifier, and thus provides a low noise operational amplifier that may be utilized in various applications, environments, systems, and/or the like.

Additionally, by utilizing common-tail transistors at the first amplifier stage of the operational amplifier for the purpose of current-biasing and for the purpose of applying common-mode-feedback respectively, embodiments of the present disclosure have good common-mode-rejection-ratio, especially for the first amplifier stage. This mitigates the impact of any variation in the input common mode of the operational amplifier on its performance and helps ensure common-mode stability of the two-stage operational amplifier, when it is used within an external feedback loop, for example in the case of multiplying DAC in pipelined ADC.

Additionally, by utilizing a capacitively-biased inverter amplifier at the second amplifier stage corresponding to the output stage of the operational amplifier, embodiments of the present disclosure provide a wide output swing with a stable output common-mode. This is possible since the effective supply of the output stage, which is the difference between potentials of source terminals of the PMOS and NMOS transistors of the output stage, remains almost fixed at the difference between external supply and ground, and does not vary with process and temperature. This ensures maximum headroom for the transistors of the output stage, thus enabling wide output swing which can be centered around mid-point of the supply.

Additionally, by using both PMOS and NMOS transistors as drivers, the transconductance (e.g., gₘ) of the respective amplifier stage is effectively doubled. It would be appreciated that noise, bandwidth, and current consumption generally relate (e.g., linked) to the transconductance (e.g., input gm) of an operational amplifier. Accordingly, by using both PMOS and NMOS transistors of an amplifier stage as a driver, embodiments of the present disclosure provide lower noise, higher bandwidth, and lower current consumption, for example, a least in part due to the increased transconductance enabled by utilizing dual PMOS and NMOS driver configuration.

As described above, operational amplifiers may be utilized in various applications, environments, and/or systems. Non-limiting examples of applications, environments, and/or systems where an operational amplifier may be utilized include pipelined ADC, pipelined-SAR ADC, and/or the like. Various applications, environments, and/or systems may have different operational amplifier requirements (e.g., different bandwidth requirements, different noise requirements, and/or the like). Additionally or alternatively, various applications, environments, and/or systems may use an operational amplifier in different ways. For example, in an example context, a pipelined ADC may use an operational amplifier as a residue amplifier.

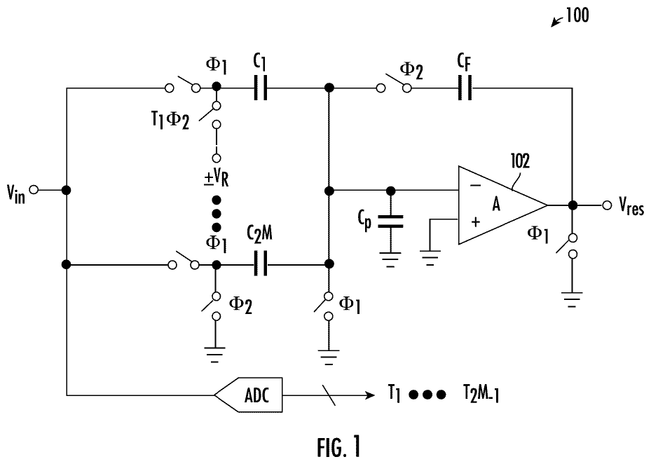

FIG. 1 illustrates an example application where an operational amplifier may be utilized. Specifically, FIG. 1 illustrates an example MDAC circuit 100 of a pipelined ADC. As shown, in FIG. 1, the MDAC circuit includes an operational amplifier 102, which is used as the core in the MDAC to implement gain. In various implementations, to use an operational amplifier in a pipelined ADC as a residue amplifier, the pipelined ADC requires that the operational amplifier have a high gain, a low noise and wide output swing. Moreover, it is desirable to satisfy these operational amplifier requirements (e.g., high gain, low noise, and wide output swing) while efficiently consuming power. An example operational amplifier according to embodiments of the present disclosure may be utilized to satisfy the noted high gain, low noise, and wide output swing requirements while also mitigating the amount of power consumed. In some embodiments, the example operational amplifier is a two-stage operational amplifier.

While the description above provides an example MDAC and/or pipelined ADC, it is noted that the scope of the present disclosure is not limited to the description above. Example embodiments of the present disclosure may be implemented in other applications and/or systems. For example, other applications and/or systems may require an operational amplifier with high gain, low noise, and wide output swing for a variety of reasons other than use of the operational amplifier as a residue amplifier.

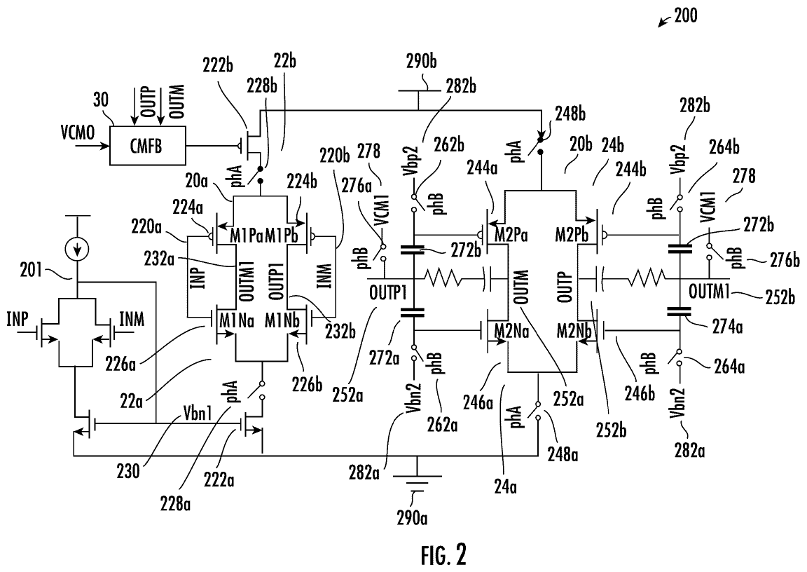

FIG. 2, illustrates an example operational amplifier 200 in accordance with at least one embodiment of the present disclosure. Specifically FIG. 2 illustrates an example discrete time implementation of an example operational amplifier circuit according to at least one embodiment of the present disclosure. In some embodiments, the example operational amplifier 200 comprises a first amplifier stage 20a representing an input stage of the operational amplifier and a second amplifier stage 20b representing an output stage of the operational amplifier 200. For example, in some embodiments, the first amplifier stage 20a is an input stage of the operational amplifier 200, and the second amplifier stage 20b is an output stage of the operational amplifier 200. In this regard, the first amplifier stage 20a may comprise a first gain stage and the second amplifier stage 20b may comprise a second gain stage of the operational amplifier 200.

In some embodiments, the first amplifier stage 20a comprises a first inverter 22a and a second inverter 22b. In some embodiments, the first inverter 22a comprises a first PMOS transistor 224a and a first NMOS transistor 226a. In some embodiments, the second inverter 22b comprises a second PMOS transistor 224b and a second NMOS transistor 226b. The first inverter 22a and the second inverter 22b may be configured to operate in a differential fashion. For example, in some embodiments, the first inverter 22a and the second inverter 22b comprise or otherwise function as differential inverters. It should be appreciated that in some embodiments, the first inverter 22a and the second inverter 22b may comprise a different inverter configuration. For example, in some embodiments, the first inverter 22a may comprise transistors of a different type and/or arranged in a different configuration.

In some embodiments, the gate terminal of the first PMOS transistor 224a and the gate terminal of the first NMOS transistor 226a form or otherwise define a first input 220a. In some embodiments, the gate terminal of the second PMOS transistor 224b and the gate terminal of the second NMOS transistor 226b form or otherwise define a second input 220b. For example, in some embodiments, the gate terminal of each of the first PMOS transistor 224a and the first NMOS transistor 226a are coupled together, while the gate terminal of each of the second PMOS transistor 224b and the second NMOS transistor 226b are coupled together.

In some embodiments, the drain terminal of the first PMOS transistor 224a and the drain terminal of the first NMOS transistor 226a are coupled together, and form or otherwise define a first output 232a of the first amplifier stage 20a. In some embodiments, the drain terminal of the second PMOS transistor 224b and the gate terminal of the second NMOS transistor 226b are coupled together, and form or otherwise define a second output 232b of the first amplifier stage 20a. For example, in some embodiments, the first amplifier stage 20a is configured to output a first output 232a via the drain terminals of the first PMOS transistor 224a and first NMOS transistor 226a, and output a second output 232b via the drain terminals of the second PMOS transistor 224b and the second NMOS transistor 226b.

In some embodiments, the first output 232a and the second output 232b of the first amplifier stage 20a are coupled to the second amplifier stage 20b. As described herein, in some embodiments, the first output 232a and the second output 232b are provided as input to the second amplifier stage 20b. In some embodiments, the first output 232a is capacitively coupled to a portion of the second amplifier stage 20b (e.g., to one or more components of the second amplifier stage 20b). Additionally or alternatively, in some embodiments, the first output 232a is coupled to a portion of the second amplifier stage 20b (e.g., to one or more components of the second amplifier stage 20b) via a first RC circuit, where the first RC circuit comprises a resistor and a capacitor. Additionally or alternatively, in some embodiments, the first output 232a is selectively coupled to a voltage 278 via a switch 276a. The switch 276a may be referred to as a biasing switch.

In some embodiments, the second output 232b is capacitively coupled to a portion of the second amplifier stage 20b (e.g., to one or more components of the second amplifier stage 20b). Additionally or alternatively, in some embodiments, the second output 232b is coupled to a portion of the second amplifier stage 20b (e.g., to one or more components of the second amplifier stage 20b) via a second RC circuit, where the second RC circuit comprises a resistor and a capacitor. Additionally or alternatively, in some embodiments, the second output 232b is selectively coupled to a voltage 278 via a switch 276b. The switch 276b may be referred to as a biasing switch.

In some embodiments, the source terminals of the first NMOS transistor 226a and the source terminal of the second NMOS transistor 226b are selectively coupled to a first common-tail transistor 222a configured to define the bias current. As shown in FIG. 2, in some embodiments, the gate terminal of the first common-tail transistor 222a is coupled to a bias voltage 230. The first common-tail transistor 222a, for example, may be connected to a bias current circuit 201. In this regard, the first inverter 22a and the second inverter 22b may have input currents going through the respective first and second inverters 22a, 22b biased with the first common-tail transistor 222a (e.g., defining the gate potential of the first common-tail transistor 222a). While the first common-tail transistor 222a is depicted in FIG. 2 as an NMOS type transistor, it should be appreciated that the first common-tail transistor 222a may be of a different type, for example, a PMOS type.

In some embodiments, a first switch 228a is disposed between the drain terminal of the first common-tail transistor 222a and the source terminals of the first and second NMOS transistors 226a, 226b to facilitate selective coupling of the first common-tail transistor 222a to the first and second NMOS transistors 226a, 226b. In some embodiments, a first end of the first switch 228a is coupled to the drain terminal of the first common-tail transistor 222a and a second end of the first switch 228a is coupled to the source terminals of the first and second NMOS transistors 226a, 226b. The first switch 228a may be referred to an amplifier switch.

In some embodiments, by utilizing common-tail transistors, such as the first common-tail transistor 222a at the first amplifier stage (e.g., input stage) to define the biasing current, and the second common-tail transistor 222b to apply the common-mode-feedback, embodiments of the present disclosure mitigate or reduce the effect of any variation in the input common mode of the amplifier on its performance. Accordingly, embodiments, of the present disclosure provide good common-mode-rejection-ratio and in turn good common-mode stability. For example, the absence of common-tail transistors can lead to poor common mode rejection ratio (CMRR). In various contexts, a poor CMRR is particularly undesirable in a two-stage operational amplifier when it is used within an outside feedback loop. Here, the outside loop might provide negative-feedback in differential mode, but in common-mode the operational amplifier would be in positive feedback. Accordingly, a poor CMRR coupled with positive feedback may result in common-mode instability.

In some embodiments, the source terminals of the first PMOS transistor 224a and the source terminal of the second PMOS transistor 224b are selectively coupled to a second common-tail transistor 222b. As shown in FIG. 2, in some embodiments, the gate terminal of the second common-tail transistor 222b is coupled to a common-mode feedback circuit (CMFB) 30 (depicted as a functional block for ease of illustrating the example operational amplifier 200). For example, the gate voltage of the second common-tail transistor 222b may be controlled by the output of the common-mode feedback circuit 30. While the second common-tail transistor 222b is depicted in FIG. 2 as a PMOS type transistor, it should be appreciated that the second common-tail transistor 222b may be of NMOS type.

In some embodiments, a second switch 228b is disposed between the drain terminal of the second common-tail transistor 222b and the source terminals of the first and second PMOS transistors 224a, 224b to facilitate selective coupling of the second common-tail transistor 222b to the first and second PMOS transistors 224a, 224b. In some embodiments, a first end of the second switch 228b is coupled to the drain terminal of the second common-tail transistor 222b and a second end of the first switch 228a is coupled to the source terminals of the first and second PMOS transistors 224a, 224b. The second switch 228b may be referred to an amplifier switch.

In some embodiments, and as illustrated in FIG. 2, the first amplifier stage 20a does not include a biasing capacitor. In this regard, the first amplifier stage 20a will not be associated with or otherwise generate KT/C noise that are generally associated with biasing capacitors. Accordingly, embodiments of the present disclosure provide an operational amplifier with low noise at least in part due to the absence of biasing capacitor(s) in the first amplifier stage.

In some embodiments, the first and second switches 228a, 228b are configured to facilitate multi-phase operation of the example operational amplifier 200. For example, in some embodiments, the operational amplifier 200 is configured to operate in a first phase corresponding to a biasing phase, and a second phase corresponding to an amplification phase. In some embodiments, the switches 228a and 228b are open (e.g., in a opened state) during the biasing phase.

As illustrated in FIG. 2, in some embodiments, the PMOS and NMOS transistors of both the first and second amplifier stages are used as drivers, whereby using both PMOS and NMOS transistors as drivers effectively doubles the transconductance (e.g., gₘ) of the amplifier stages. For example, where the NMOS transistors and the PMOS transistors both have the same transconductance, the transconductance for the operational amplifier 200 effectively doubles, which, in turn, facilitates lower noise, higher bandwidth, and lower current consumption.

In some embodiments, the second amplifier stage 20b corresponding to the output stage of the example operational amplifier 200 comprises a third inverter 24a and fourth inverter 24b. In some embodiments, the third inverter 24a comprises a third PMOS transistor 244a and a third NMOS transistor 246a. In some embodiments, the fourth inverter 24b comprises a fourth PMOS transistor 244b and a fourth NMOS transistor 246b. In some embodiments, the third inverter 24a and the fourth inverter 24b are configured to operate in a differential fashion. For example, in some embodiments, the third inverter 24a and the fourth inverter 24b comprise or otherwise function as differential inverters. It should be appreciated that in some embodiments, the third inverter 24a and the fourth inverter 24b may comprise a different inverter configuration. For example, in some embodiments, the third inverter 24a may comprise transistors of a different type and/or arranged in a different configuration.

In some embodiments, the gate terminal of the third PMOS transistor 244a and the gate terminal of the third NMOS transistor 246a are each coupled to the first output 232a of the first amplifier stage 20a. In some embodiments, the gate terminal of the fourth PMOS transistor 244b and the gate terminal of the fourth NMOS transistor 246b are each coupled to the second output 232b of the first amplifier stage 20a. As further described herein, in some embodiments, the gate terminal of the third PMOS transistor 244a and the gate terminal of the third NMOS transistor 246a are capacitively coupled to the first output 232a of the first amplifier stage 20a, and the gate terminal of the fourth PMOS transistor 244b and the gate terminal of the fourth NMOS transistor 246b are capacitively coupled to the second output 232b of the first amplifier stage 20a.

In some embodiments, the drain terminal of the third PMOS transistor 244a and the drain terminal of the third NMOS transistor 246a are coupled together and define a first output 252a of the second amplifier stage 20b. In some embodiments, the drain terminal of the fourth PMOS transistor 244b and the gate terminal of the fourth NMOS transistor 246b are coupled together and define a second output 252b of the second amplifier stage 20b. For example, in some embodiments, the second amplifier stage 20b is configured to output a first output 252a via the drain terminals of the third PMOS transistor 244a and third NMOS transistor 246a, and output a second output 252b via the drain terminals of the fourth PMOS transistor 244b and the fourth NMOS transistor 246b. As illustrated in FIG. 2, in some embodiments, the drain terminals of the third PMOS transistor 244a and third NMOS transistor 246a are coupled to the first output 232a of the first amplifier stage 20a via a first RC circuit, and the drain terminals of the fourth NMOS transistor 246b are coupled to the second output 232b of the first amplifier stage 20a via a second RC circuit.

In some embodiments, the source terminals of the third NMOS transistor 246a and the source terminal of the fourth NMOS transistor 246b are selectively coupled to a ground 290a. In some embodiments, a third switch 248a is disposed between the ground 290a and the source terminals of the third and fourth NMOS transistors 246a, 246b to facilitate selective coupling of the ground 290a to the third and fourth NMOS transistors 246a, 246b. The third switch 248a may be referred to as an amplifier switch. In some embodiments, a first end of the third switch 248a is coupled to the ground 290a and a second end of the third switch 248a is coupled to the source terminals of the third and fourth NMOS transistors 246a, 246b.

In some embodiments, the source terminals of the third PMOS transistor 244a and the source terminal of the fourth PMOS transistor 244b are selectively coupled to a voltage supply 290b. In some embodiments, a fourth switch 248b is disposed between the voltage supply 290b and the source terminals of the third and fourth PMOS transistors 244a, 244b to facilitate selective coupling of the voltage supply 290b to the third and fourth NMOS transistors 246a, 246b. The fourth switch 248b may be referred to as an amplifier switch. In some embodiments, a first end of the fourth switch 248b is coupled to the voltage supply 290b and a second end of the fourth switch 248b is coupled to the source terminals of the third and fourth PMOS transistors 244a, 244b. In some embodiments, the third and fourth switches 248a, 248b are configured to facilitate multi-phase operation of the example operational amplifier 200. For example, as described above, in some embodiments, the operational amplifier 200 is configured to operate in a first phase corresponding to a biasing phase, and a second phase corresponding to an amplification phase. In some embodiments, the third switch 248a and the fourth switch 248b are open (e.g., opened state) during the biasing phase and are closed (e.g., closed state) during the amplification phase.

As described above, in some embodiments, the gate terminal of the third PMOS transistor 244a and the gate terminal of the third NMOS transistor 246a are capacitively coupled to the first output 232a of the first amplifier stage 20a, and the gate terminal of the fourth PMOS transistor 244b and the gate terminal of the fourth NMOS transistor 246b are capacitively coupled to the second output 232b of the first amplifier stage 20a. In this regard, in some embodiments, the second amplifier stage 20b is capacitively biased. In some embodiments and as depicted in FIG. 2, the second amplifier stage 20b includes a first switched-capacitor circuit coupled to the third inverter 24a. For example, the gate terminal of the third PMOS transistor 244a and the gate terminal of the third NMOS transistor 246a are capacitively coupled to the first output 232a via the first switched-capacitor circuit, where a portion of the first switched-capacitor circuit may be coupled to the gate terminal of the third PMOS transistor 244a, and a portion of the first switched-capacitor circuit may be coupled to the gate terminal of the third NMOS transistor 246a. Additionally or alternatively, in some embodiments, the second amplifier stage 20b includes a second switched capacitor circuit coupled to the fourth inverter 24b. For example, the gate terminal of the fourth PMOS transistor 244b and the gate terminal of the fourth NMOS transistor 246b are capacitively coupled to the second output 232b via the second switched-capacitor circuit, where a portion of the second switched-capacitor circuit may be coupled to the gate terminal of the fourth PMOS transistor 244b, and a portion of the second switched-capacitor circuit may be coupled to the gate terminal of the fourth NMOS transistor 246b.

In some embodiments, the first switched-capacitor circuit includes a first capacitor 272a and a second capacitor 272b each coupled to the first output 232a of the first amplifier stage 20a. In some embodiments, the first capacitor 272a is coupled to the gate terminal of the third NMOS transistor 246a. In some embodiments, the second capacitor 272b is coupled to the gate terminal of the third PMOS transistor 244a. In some embodiments, the second switched-capacitor circuit includes a third capacitor 274a and a fourth capacitor 274b each coupled to the second output 232b of the first amplifier stage 20a. In some embodiments, the third capacitor 274a is coupled to the gate terminal of the fourth NMOS transistor 246b. In some embodiments, the fourth capacitor 274b is coupled to the gate terminal of the fourth PMOS transistor 244b.

In some embodiments, the first switched-capacitor circuit includes a first switch 262a and a second switch 262b. The first switch 262a and the second switch 262b may each be referred to as a biasing switch. A first end of the first switch 262a may be coupled to the capacitor 272a and the gate of the third NMOS transistor 246a, and a second end of the first switch 262a may be coupled to a bias voltage 282a. A first end of the second biasing switch 262b may be coupled to the capacitor 272b and the gate of the third PMOS transistor 244a, and a second end of the second biasing switch 262b may be coupled to a bias voltage 282b.

In some embodiments, the second switched-capacitor circuit includes a third switch 264a and a fourth switch 264b. The third switch 264a and the fourth switch 264b may each be referred to as a biasing switch. A first end of the third switch 264a may be coupled to the capacitor 274a and the gate of the fourth NMOS transistor 246b, and a second end of the third switch 264a may be coupled to the bias voltage 282a. A first end of the fourth switch 264b may be coupled to the capacitor 274b and the gate of the fourth PMOS transistor 244b, and a second end of the fourth switch 264b may be coupled to the bias voltage 282b. In some embodiments, the bias voltage 282a correspond to or otherwise defines the gate potential of the third NMOS transistor 246a and fourth NMOS transistor 246b. In some embodiments, the bias voltage 282b correspond to or otherwise defines the gate potential of the third PMOS transistor 244a and the fourth PMOS transistor 244b.

In this regard, the gate terminals of the third NMOS transistor 246a and fourth NMOS transistor 246b are selectively coupled to the bias voltage 282a via the first switch 262a and the third switch 264a, and the gate terminals of the third PMOS transistors 244a and the fourth PMOS transistor 244b are selectively coupled to the bias voltage 282b via the first switch 262a and the fourth switch 264b.

In some embodiments, the switches 262a, 262b, 264a, 264b are configured to facilitate multi-phase operation of the example operational amplifier 200. For example, as described above, in some embodiments, the operational amplifier 200 may be configured to operate in a first phase corresponding to a biasing phase, and a second phase corresponding to an amplification phase. In some embodiments, in the first phase (e.g., biasing phase), the switches 262a, 262b, 264a, 264b are closed (e.g., in a closed state), causing the third NMOS transistor 246a and fourth NMOS transistor 246b to be coupled to the bias voltage 282a, and causing the gate terminal of the third PMOS transistor 244a and gate terminal of the fourth PMOS transistor 244b to be coupled to the bias voltage 282b. In some embodiments, in the second phase (e.g., amplification phase), the switches 262a, 262b, 264a, 264b are opened (e.g., in an opened state), causing the variation in the input to be reflected on the gates of each PMOS and NMOS transistors (e.g., 244a, 244b, 246a, 246b) of the pair of inverters 24a, 24b of the second amplifier stage 20b, while the center point around which they are varying remains at the gate potential/bias voltage 282a, 282b.

In some embodiments, the biasing capacitors 272a, 272b, 274a, 274b may be refreshed (e.g., periodically) with the bias voltage 282a, 282b during the biasing phase (e.g., when the operational amplifier 200 is not being used) and function as floating batteries between the input and the gate terminals of the PMOS and NMOS transistors of the pair of inverters 24a, 24b of the second amplifier stage 20b. As described above, the input may comprise or otherwise correspond to the first output 232a and the second output 232b of the first amplifier stage 20a.

In some embodiments, the first output 232a of the first amplifier stage 20a is coupled to the drain terminals of the third PMOS transistor 244a and the third NMOS transistor 246a. In some embodiments, the first output 232a of the first amplifier stage 20a is coupled to the drain terminals of the third PMOS transistor 244a and the third NMOS transistor 246a via a first RC circuit comprising a resistor and a capacitor. In some embodiments, the second output 232b of the first amplifier stage is coupled to the fourth capacitor 274b) of the second amplifier stage 20b and the drain terminals of the third PMOS transistor 244a and the third NMOS transistor 246a. In some embodiments, the second output 232b of the first amplifier stage 20a is coupled to the drain terminals of the third PMOS transistor 244a and the third NMOS transistor 246a via a second RC circuit comprising a resistor and a capacitor.

In some embodiments, the drain terminal of the third PMOS transistor 244a and the drain terminal of the third NMOS transistor 246a are coupled together and form or otherwise define a first output 252a of the second amplifier stage 20b. In some embodiments, the drain terminal of the fourth PMOS transistor 244b and the drain terminal of the fourth NMOS transistor 246b are coupled together and form or otherwise define a second output 252b of the second amplifier stage 20b. For example, in some embodiments, the second amplifier stage 20b is configured to output a first output 252a via the drain terminals of the third PMOS transistor 244a and third NMOS transistor 246a, and output a second output 252b via the drain terminals of the fourth PMOS transistor 244b and the fourth NMOS transistor 246b. In some embodiments, the first output 252a and the second output 252b of the second amplifier stage 20b are coupled to the common-mode feedback circuit 30. For example, in some embodiments, the first output 252a and the second output 252b are provided as input to the common-mode feedback circuit 30.

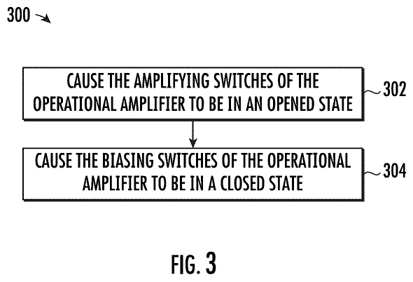

As described above, the example operational amplifier 200 is capable of operating in two phases. In some embodiments, the operational amplifier 200 is capable of operating in a first phase representing a biasing phase and a second phase representing an amplification phase. FIG. 3 illustrates a flowchart depicting operations of an example operational amplifier in a biasing phase in accordance with at least one example embodiment of the present disclosure. Specifically, FIG. 3 depicts an example process 300. In some embodiments, the example method 300 may be implemented by an example operational amplifier 200 described herein in connection with FIG. 2.

According to some examples, the method includes causing the amplifying switches of the operational amplifier to be in an opened state at operation 302. For example, the example method includes causing the switches 228a, 228b coupled to the inverters of the first amplifier stage 20a to be in opened state, and causing the switches 248a and 248b coupled to the second amplifier stage 20b to be in an opened state, whereby the pair of inverters of the first amplifier stage and the pair of inverters of the second amplifier stage are disconnected from their respective supply and ground.

According to some examples, the method includes causing the biasing switches of the operational amplifier to be in a closed state at operation 304. For example, the example method includes causing the switches 262a, 262b, 264a, 264b coupled to the inverters of the second amplifier stage 20b to be in a closed state, and causing the switches 276a, 276b coupled to the first output and second output of the first amplifier stage 20a to be in a closed state. In this regard, by causing the biasing switches coupled to the PMOS and NMOS transistors of the second stage to be in a closed state, the corresponding biasing potential is applied to each gate of the PMOS and NMOS transistors of the second stage. For example, in some embodiments, the gate terminals of the PMOS and NMOS transistors of the inverter of second amplifier stage are coupled to their respective biasing potentials during the biasing phase. For example, PMOS transistors 244a, 244b are coupled to bias voltage 282b, and NMOS transistors 246a, 246b are coupled to the bias voltage 282a. In this regard, by causing the biasing switches coupled to the first output 232a and second output 232b of the first amplifier stage 20a to be in a closed state, the first and second outputs of the first amplifier stage are coupled to the voltage 278, for example, switched to a fixed voltage. In this regard, in some embodiments, a voltage drop (e.g., “Vbp-VCM1” and “Vbn-VCM1”) is stored across the biasing capacitors. In some embodiments, such stored voltage drop is used as floating batteries during the amplification phase to set proper current biasing in the second amplifier stage.

In this regard, during the biasing phase, both the first amplifier stage and the second amplifier stage are turned off. For example, during the biasing phase, the first amplifier stage and the second amplifier stage do not consume current. Accordingly, embodiments, of the present disclosure facilitate efficient power consumption in various applications. For example, in a pipelined ADC that includes a sampling phase and a multiplication phase, where the operational amplifier is used during the multiplication phase but not used during the sampling phase. In such example, the operational amplifier can be caused to operate in a biasing phase as described herein during the sampling phase of the pipelined ADC.

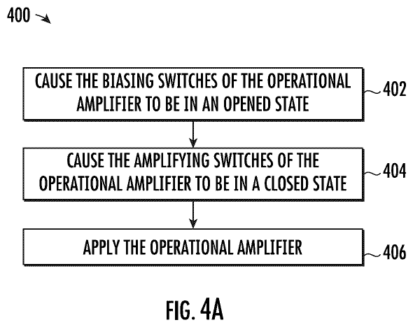

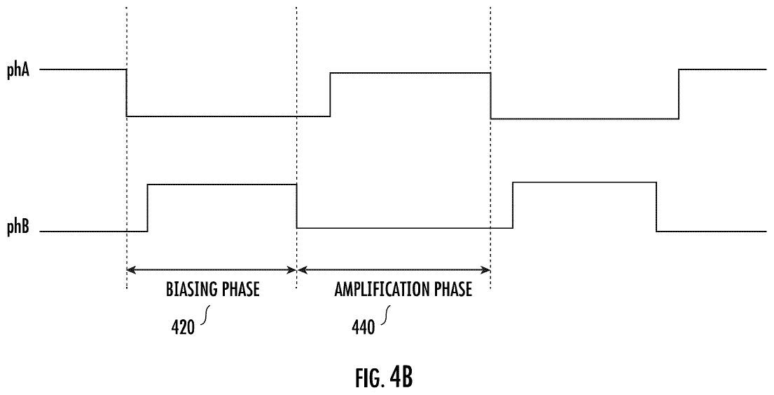

FIG. 4A illustrates a flowchart depicting operations of an example operational amplifier in an amplification phase in accordance with at least one example embodiment of the present disclosure. Specifically, FIG. 4A depicts an example process 400. In some embodiments, the example method 400 may be implemented by an example operational amplifier 200 described herein in connection with FIG. 2.

According to some examples, the method includes causing the biasing switches of the operational amplifier to be in an opened state at operation 402. For example, the example method includes causing the switches 262a, 262b, 264a, 264b coupled to the inverters of the second amplifier stage 20b to be in an opened state, and causing the switches 276a, 276b coupled to the first output and second output of the first amplifier stage 20a to be in an opened state. In this regard, by causing the biasing switches coupled to the PMOS and NMOS transistors of the second amplifier stage 20b to be in an opened state, the corresponding biasing potential is not applied to the gates of the PMOS and NMOS transistors of the second amplifier stage 20b. For example, in some embodiments, the gate terminals of the PMOS and NMOS transistors of the inverter of the second amplifier stage 20b are not coupled to their respective biasing potentials during the amplification phase. For example, PMOS transistors 244a, 244b are not coupled to bias voltage 282b, and NMOS transistors 246a, 246b are not coupled to the bias voltage 282a. In this regard, by causing the biasing switches coupled to the first output and second output of the first amplifier to be in an opened state, the first and second outputs of the first amplifier stage are not coupled to the voltage 278, for example, not switched to a fixed voltage.

According to some examples, the method includes causing the amplifying switches of the operational amplifier to be in a closed state at operation 404. For example, the example method includes causing the switches 228a, 228b coupled to the inverters of the first amplifier stage 20a to be in a closed state, and causing the switches 248a and 248b coupled to the second amplifier stage 20b to be in a closed state, whereby the pair of inverters of the first amplifier stage and the pair of inverters of the second amplifier stage are connected to their respective supply and ground.

According to some examples, the method includes applying the operational amplifier. at operation 406. In some embodiments, applying the operational amplifier includes causing the first inverter stage to generate output voltages that are input to the second amplifier stage, and causing the second amplifier stage to generate output(s).

FIG. 4B provides an example timing diagram corresponding to a bias phase and an amplification phase in accordance with at least one example embodiment of the present disclosure. As shown in FIG. 4B, in some embodiments, the operation phases (e.g., biasing phase 420 and amplification phase 440) are non-overlapping.

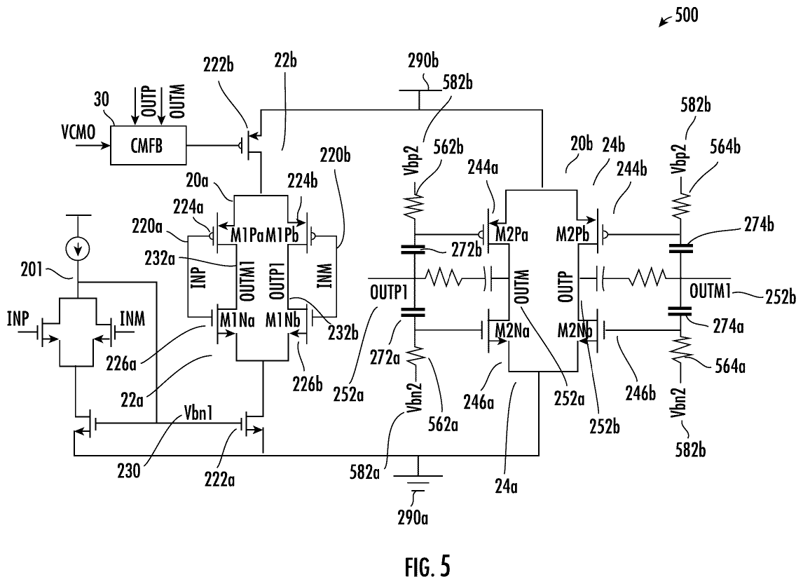

FIG. 5, illustrates an example operational amplifier 200 in accordance with at least one embodiment of the present disclosure. Specifically FIG. 5 illustrates an example continuous time implementation of an example operational amplifier circuit according to at least one embodiment of the present disclosure. The operational amplifier 500 includes aspects, parts, etc. that are similar to the example operational amplifier 500. Accordingly, parts that are similar and already shown in relation to FIG. 2 may be depicted in FIG. 5 by the same reference numbers.

The example operational amplifier 500 shown in FIG. 5 may be configured to have a continuous current flowing through the operational amplifier 500. In this regard, the operational amplifier 500 may operate in a single phase. In some embodiments, the operational amplifier 500 shown in FIG. 5 comprises a first amplifier stage 20a corresponding to an input stage of the operational amplifier and a second amplifier stage 20b corresponding to an output stage of the operational amplifier 500. The first amplifier stage 20a and the second amplifier stage 20b may comprise the gain stages of the operational amplifier 500. In some embodiments and as illustrated in FIG. 5, each amplifier stage (e.g., first amplifier stage 20a and second amplifier stage 20b) comprise inverters.

In some embodiments, the first amplifier stage 20a representing an input stage of the example operational amplifier comprises a first inverter 22a and second inverter 22b. In some embodiments, the first inverter 22a comprises a first PMOS transistor 224a and a first NMOS transistor 226a. In some embodiments, the second inverter 22b comprises a second PMOS transistor 224b and a second NMOS transistor 226b. The first inverter 22a and the second inverter 22b may be configured to operate in a differential fashion. For example, in some embodiments, the first inverter 22a and the second inverter 22b comprise or otherwise function as differential inverters. It should be appreciated that in some embodiments, the first inverter 22a and the second inverter 22b may comprise a different inverter configuration. For example, in some embodiments, the first inverter 22a may comprise transistors of a different type and/or arranged in a different configuration.

In some embodiments, the gate terminal of the first PMOS transistor 224a and the gate terminal of the first NMOS transistor 226a are each coupled to a first input 220a. In some embodiments, the gate terminal of the second PMOS transistor 224b and the gate terminal of the second NMOS transistor 226b are each coupled to a second input 220b. For example, in some embodiments, the gate terminal of each of the first PMOS transistor 224a and the first NMOS transistor 226a are coupled together, while the gate terminal of each of the second PMOS transistor 224b and the second NMOS transistor 226b are coupled together.

In some embodiments, the drain terminal of the first PMOS transistor 224a and the drain terminal of the first NMOS transistor 226a are coupled together and define a first output 232a of the first amplifier stage 20a. In some embodiments, the drain terminal of the second PMOS transistor 224b and the gate terminal of the second NMOS transistor 226b are coupled together and define a second output 232b of the first amplifier stage 20a. For example, in some embodiments, the first amplifier stage 20a is configured to output a first output 232a via the drain terminals of the first PMOS transistor 224a and first NMOS transistor 226a, and output a second output 232b via the drain terminals of the second PMOS transistor 224b and the second NMOS transistor 226b. In some embodiments, the first output 232a and the second output 232b of the first inverter stage are coupled to the second amplifier stage 20b. For example, in some embodiments, the first output 232a and the second output 232b are provided as input to the second amplifier stage 20b.

In some embodiments, the first output 232a and the second output 232b of the first amplifier stage 20a are coupled to the second amplifier stage 20b. As described herein, in some embodiments, the first output 232a and the second output 232b are provided as input to the second amplifier stage 20b. In some embodiments, the first output 232a is capacitively coupled to a portion of the second amplifier stage 20b (e.g., to one or more components of the second amplifier stage 20b). Additionally or alternatively, in some embodiments, the first output 232a is coupled to a portion of the second amplifier stage 20b (e.g., to one or more components of the second amplifier stage 20b) via a first RC circuit, where the first RC circuit comprises a resistor and a capacitor. Additionally or alternatively, in some embodiments, the first output 232a is coupled to a first resistor, where the resistor is coupled to a voltage 278.

In some embodiments, the second output 232b is capacitively coupled to a portion of the second amplifier stage 20b (e.g., to one or more components of the second amplifier stage 20b). Additionally or alternatively, in some embodiments, the second output 232b is coupled to a portion of the second amplifier stage 20b (e.g., to one or more components of the second amplifier stage 20b) via a second RC circuit, where the second RC circuit comprises a resistor and a capacitor. Additionally or alternatively, in some embodiments, the second output 232b is coupled to a second resistor, where the resistor is coupled to voltage 278.

In some embodiments, the source terminals of the first NMOS transistor 226a and the source terminal of the second NMOS transistor 226b are coupled to a first common-tail transistor 222a configured to define the bias current. As shown in FIG. 5, in some embodiments, the gate terminal of the first common-tail transistor 222a is coupled to a bias voltage 230 (e.g., defining the gate potential of the first common-tail transistor 222a). The first common-tail transistor 222a, for example, may be connected to a bias current circuit 201. In this regard, the first inverter 22a and the second inverter 22b may have input currents going through the first and second inverters 22a, 22b biased with the first common-tail transistor 222a. While the first common-tail transistor 222a is depicted in FIG. 2 as an NMOS type transistor, it should be appreciated that the first common-tail transistor 222a may be of a different type, for example, a PMOS type.

As described above in connection to FIG. 2, by utilizing a common-tail transistor, 222a at the first amplifier stage (e.g., input stage) to define the biasing current at the input stage of the operational amplifier 500, and utilizing another common-tail transistor 222b at the input stage to apply common-mode-feedback, embodiments of the present disclosure mitigates the effect of any variation in the input common mode and thus provides common mode stability. For example, the absence of a common-tail transistors can lead to poor common mode rejection ratio (CMRR).

In some embodiments, the source terminals of the first PMOS transistor 224a and the source terminal of the second PMOS transistor 224b are coupled to a second common-tail transistor 222b. In some embodiments, the gate terminal of the second common-tail transistor 222b is coupled to a common-mode feedback circuit 30 (depicted as a functional block for ease of illustrating the example operational amplifier 500). For example, the gate voltage of the second common-tail transistor 222b may be controlled by the output of the common-mode feedback circuit 30. While the second common-tail transistor 222b is depicted in FIG. 5 as a PMOS type transistor, it should be appreciated that the second common-tail transistor 222b may be of NMOS type.

In some embodiments, and as illustrated in FIG. 2, the first amplifier stage 20a does not include a biasing capacitor. In this regard, the first amplifier stage 20a will not be associated with or otherwise generate KT/C noise resulting from biasing capacitors. Accordingly, embodiments of the present disclosure provide an operational amplifier with low noise at least in part due to the absence of biasing capacitor in the first amplifier stage (e.g., input stage).

As illustrated, in some embodiments, the PMOS and NMOS transistors of the first amplifier stage are configured to be used as drivers. By using both PMOS and NMOS transistors as drivers, the transconductance (e.g., gₘ) of the first amplifier stage 20a is effectively doubled. For example, where the NMOS transistors and the PMOS transistors both have the same transconductance, the transconductance for the operational amplifier 500 effectively doubles, which, in turn, facilitates lower noise, higher bandwidth, and lower current consumption.

In some embodiments, the second amplifier stage 20b corresponding to the output stage of the example operational amplifier 500 comprises a third inverter 24a and fourth inverter 24b. In some embodiments, the third inverter 24a comprises a third PMOS transistor 244a and a third NMOS transistor 246a. In some embodiments, the fourth inverter 24b comprises a fourth PMOS transistor 244b and a fourth NMOS transistor 246b. In some embodiments, the third inverter 24a and the fourth inverter 24b are configured to operate in a differential fashion. For example, in some embodiments, the third inverter 24a and the fourth inverter 24b comprise or otherwise function as differential inverters. It should be appreciated that in some embodiments, the third inverter 24a and the fourth inverter 24b may comprise a different inverter configuration. For example, in some embodiments, the third inverter 24a may comprise transistors of a different type and/or arranged in a different configuration.

In some embodiments, the gate terminal of the third PMOS transistor 244a and the gate terminal of the third NMOS transistor 246a are each coupled to the first output 232a of the first amplifier stage 20a. In some embodiments, the gate terminal of the fourth PMOS transistor 244b and the gate terminal of the fourth NMOS transistor 246b are each coupled to the second output 232b of the first amplifier stage 20a. As further described herein, in some embodiments, the gate terminal of the third PMOS transistor 244a and the gate terminal of the third NMOS transistor 246a are capacitively coupled to the first output 232a of the first amplifier stage 20a, and the gate terminal of the fourth PMOS transistor 244b and the gate terminal of the fourth NMOS transistor 246b are capacitively coupled to the second output 232b of the first amplifier stage 20a.

In some embodiments, the drain terminal of the third PMOS transistor 244a and the drain terminal of the third NMOS transistor 246a are coupled together and define a first output 252a of the second amplifier stage 20b. In some embodiments, the drain terminal of the fourth PMOS transistor 244b and the gate terminal of the fourth NMOS transistor 246b are coupled together and define a second output 252b of the second amplifier stage 20b. For example, in some embodiments, the second amplifier stage 20b is configured to output a first output 252a via the drain terminals of the third PMOS transistor 244a and third NMOS transistor 246a, and output a second output 252b via the drain terminals of the fourth PMOS transistor 244b and the fourth NMOS transistor 246b.

In some embodiments, the source terminals of the fourth NMOS transistor 246b and the source terminal of the fourth NMOS transistor 246b are coupled to a ground 290a. In some embodiments, the source terminals of the third PMOS transistor 244a and the source terminal of the fourth PMOS transistor 244b are coupled to a voltage supply 290b.

As described above, in some embodiments, the gate terminal of the third PMOS transistor 244a and the gate terminal of the third NMOS transistor 246a are capacitively coupled to the first output 232a of the first amplifier stage 20a, and the gate terminal of the fourth PMOS transistor 244b and the gate terminal of the fourth NMOS transistor 246b are capacitively coupled to the second output 232b of the first amplifier stage 20a. In this regard, in some embodiments, the second amplifier stage 20b is capacitively biased. In some embodiments and as depicted in FIG. 5, the second amplifier stage 20b includes a first capacitor circuit (which may also be referred to as a first RC circuit) coupled to the third inverter 24a. For example, the gate terminal of the third PMOS transistor 244a and the gate terminal of the third NMOS transistor 246a are capacitively coupled to the first output 232a via the first capacitor circuit, where a portion of the first capacitor circuit may be coupled to the gate terminal of the third PMOS transistor 244a, and a portion of the first capacitor circuit may be coupled to the gate terminal of the third NMOS transistor 246a. Additionally or alternatively, in some embodiments, the second amplifier stage 20b includes a second capacitor circuit (which may also be referred to as a second RC circuit) coupled to the fourth inverter 24b. For example, the gate terminal of the fourth PMOS transistor 244b and the gate terminal of the fourth NMOS transistor 246b are capacitively coupled to the second output 232b via the second capacitor circuit, where a portion of the second capacitor circuit may be coupled to the gate terminal of the fourth PMOS transistor 244b, and a portion of the second capacitor circuit may be coupled to the gate terminal of the fourth NMOS transistor 246b.

In some embodiments, the first capacitor circuit includes a first capacitor 272a and a second capacitor 272b each coupled to the first output 232a of the first amplifier stage 20a. In some embodiments, the second capacitor circuit includes a third capacitor 274a and a fourth capacitor 274b each coupled to the second output 232b of the first amplifier stage 20a.

In some embodiments, the first capacitor circuit includes a first resistor 562a and a second resistor 562b configured to facilitate biasing of the third PMOS transistor 244a and the third NMOS transistor 246a respectively. A first end of the first resistor 562a may be coupled to the capacitor 272a and the gate of the third NMOS transistor 246a, and a second end of the first resistor 562a may be coupled to a bias voltage 282a. A first end of the second resistor 562b may be coupled to the capacitor 272b and the gate of the third PMOS transistor 244a, and a second end of the second resistor 562b may be coupled to a bias voltage 582b.

In some embodiments, the second capacitor circuit includes a third resistor 564a and a fourth resistor 564b configured to facilitate biasing of the fourth MOS transistor 244b and the fourth NMOS transistor 246b respectively. A first end of the third resistor 564a may be coupled to the capacitor 274a and the gate of the fourth NMOS transistor 246b, and a second end of the third resistor 564a may be coupled to the bias voltage 282a. A first end of the fourth resistor 564b may be coupled to the capacitor 274b and the gate of the fourth PMOS transistor 244b, and a second end of the fourth resistor 564b may be coupled to the bias voltage 582b. In some embodiments, the bias voltage 282a correspond to or otherwise defines the gate potential of the third NMOS transistor 246a and fourth NMOS transistor 246b. In some embodiments, the bias voltage 282b correspond to or otherwise defines the gate potential of the third PMOS transistor 244a and the fourth PMOS transistor 244b.

In some embodiments, the first output 232a of the first amplifier stage 20a is coupled to the first capacitor circuit (e.g., at a node between the first capacitor 272a and the second capacitor 272b) of the second amplifier stage 20b and the drain terminals of the third PMOS transistor 244a and the third NMOS transistor 246a. In some embodiments, the first output 232a of the first amplifier stage 20a is coupled to the drain terminals of the third PMOS transistor 244a and the third NMOS transistor 246a via a first RC circuit comprising a resistor and a capacitor.

In some embodiments, the second output 232b of the first amplifier stage is coupled to the second capacitor circuit (e.g., at a node between the third capacitor 274a and the fourth capacitor 274b) of the second amplifier stage 20b and the drain terminals of the third PMOS transistor 244a and the third NMOS transistor 246a. In some embodiments, the second output 232b of the first amplifier stage 20a is coupled to the drain terminals of the third PMOS transistor 244a and the third NMOS transistor 246a via a second RC circuit comprising a resistor and a capacitor. In some embodiments, the drain terminal of the third PMOS transistor 244a and the drain terminal of the third NMOS transistor 246a are coupled together and define a first output 252a of the second amplifier stage 20b. In some embodiments, the drain terminal of the fourth PMOS transistor 244b and the gate terminal of the fourth NMOS transistor 246b are coupled together and define a second output 252b of the second amplifier stage 20b. For example, in some embodiments, the second amplifier stage 20b is configured to output a first output 252a via the drain terminals of the third PMOS transistor 244a and third NMOS transistor 246a, and output a second output 252b via the drain terminals of the fourth PMOS transistor 244b and the fourth NMOS transistor 246b. In some embodiments, the first output 252a and the second output 252b of the second amplifier stage 20b are coupled to the common-mode feedback circuit 30. For example, in some embodiments, the first output 252a and the second output 252b are provided as input to the common-mode feedback circuit 30.

### CONCLUSION

Many modifications and other embodiments of the disclosure set forth herein will come to mind to one skilled in the art to which this disclosure pertains having the benefit of the teachings presented in the foregoing description and the associated drawings. Therefore, it is to be understood that the embodiments are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

Further, while this detailed description has set forth some embodiments of the present disclosure, the appended claims may cover other embodiments of the present disclosure which differ from the described embodiments according to various modifications and improvements. For example, in some embodiments, the first amplifier stage and/or the second amplifier stage may comprise transistors or different types. As another example, in some embodiments, transistors of the first amplifier stage and/or the transistors of the second amplifier may be arranged and/or otherwise coupled in a different manner without departing from the scope of the present disclosure.

Further, within the appended claims, unless the specific terms “means for” or “step for” is used within a given claim, it is not intended that the claim be interpreted under 35 U.S.C. § 112, paragraph (f).

1. An operational amplifier comprising:
an input stage, the input stage comprising:
a first inverter and a second inverter coupled together and configured to operate in a differential fashion;
a first common-tail transistor selectively coupled to the first inverter and the second inverter via a first switch, the first common-tail transistor configured to define a biasing current; and
a second common-tail transistor selectively coupled to the first inverter and the second inverter via a second switch; and
an output stage, the output stage comprising:
a third inverter and a fourth inverter coupled together, the third inverter and the fourth inverter selectively coupled to a supply voltage via a third switch and selectively coupled to a ground via a fourth switch;
a first capacitive coupling configured to couple the third inverter to a first output of the input stage; and
a second capacitive coupling configured to couple the fourth inverter to a second output of the input stage.

2. The operational amplifier of claim 1 wherein:
the first inverter comprises a first PMOS transistor and a first NMOS transistor coupled together via a drain terminal of the first PMOS transistor and a drain terminal of the first NMOS transistor; and
the second inverter comprises a second PMOS transistor and a second NMOS transistor coupled together via a drain terminal of the second PMOS transistor and a drain terminal of the second NMOS transistor.

3. The operational amplifier of claim 2 wherein:
the first PMOS transistor and the second PMOS transistor are coupled together via a source terminal of the first PMOS transistor and a source terminal of the second PMOS transistor; and
the first NMOS transistor and the second NMOS transistor are coupled together via a source terminal of the first NMOS transistor and a source terminal of the second NMOS transistor.

4. The operational amplifier of claim 1 wherein:
the third inverter comprises a third PMOS transistor and a third NMOS transistor coupled together via a drain terminal of the third PMOS transistor and a drain terminal of the third NMOS transistor; and
the fourth inverter comprises a fourth PMOS transistor and a fourth NMOS transistor coupled together via a drain terminal of the fourth PMOS transistor and a drain terminal of the fourth NMOS transistor.

5. The operational amplifier of claim 4 wherein:
the third PMOS transistor and the fourth PMOS transistor are coupled together via a source terminal of the third PMOS transistor and a source terminal of the fourth PMOS transistor; and
the third NMOS transistor and the fourth NMOS transistor are coupled together via a source terminal of the third NMOS transistor and a source terminal of the fourth NMOS transistor.

6. The operational amplifier of claim 5 wherein:
a gate terminal of the third PMOS transistor and a gate terminal of the third NMOS transistor are coupled to the first output of the input stage via the first capacitive coupling; and
a gate terminal of the fourth PMOS transistor and a gate terminal of the fourth NMOS transistor are coupled to the second output of the input stage via the second capacitive coupling.

7. The operational amplifier of claim 1, wherein the first capacitive coupling comprises a first switched-capacitor circuit.

8. The operational amplifier of claim 1, wherein the second capacitive coupling comprises a second switched-capacitor circuit.

9. The operational amplifier of claim 1 further comprising:
a biasing current circuit coupled to the first common-tail transistor.

10. The operational amplifier of claim 1 further comprising:
a common-mode feedback circuit coupled to the second common-tail transistor.

11. The operational amplifier of claim 1 wherein the operational amplifier is configured to operate in one or more of a biasing phase and an amplification phase.

12. The operational amplifier of claim 11, wherein in the biasing phase, each of the first switch, the second switch, the third switch, and the fourth switch are in an opened state.

13. An operational amplifier comprising:
an input stage, the input stage comprising:
a first inverter and a second inverter coupled together and configured to operate in a differential fashion;
a first common-tail transistor coupled to the first inverter and the second inverter, the first common-tail transistor configured to define a biasing current; and
a second common-tail transistor coupled to the first inverter and the second inverter; and
an output stage, the output stage comprising:
a third inverter and a fourth inverter coupled together;
a first capacitive coupling configured to couple the third inverter to a first output of the input stage; and
a second capacitive coupling configured to couple the fourth inverter to a second output of the input stage.

14. The operational amplifier of claim 13 wherein:
the first inverter comprises a first PMOS transistor and a first NMOS transistor coupled together via a drain terminal of the first PMOS transistor and a drain terminal of the first NMOS transistor; and
the second inverter comprises a second PMOS transistor and a second NMOS transistor coupled together via a drain terminal of the second PMOS transistor and a drain terminal of the second NMOS transistor.

15. The operational amplifier of claim 14 wherein:
the first PMOS transistor and the second PMOS transistor are coupled together via a source terminal of the first PMOS transistor and a source terminal of the second PMOS transistor; and
the first NMOS transistor and the second NMOS transistor are coupled together via a source terminal of the first NMOS transistor and a source terminal of the second NMOS transistor.

16. The operational amplifier of claim 13 wherein:
the third inverter comprises a third PMOS transistor and a third NMOS transistor coupled together via a drain terminal of the third PMOS transistor and a drain terminal of the third NMOS transistor; and
the fourth inverter comprises a fourth PMOS transistor and a fourth NMOS transistor coupled together via a drain terminal of the fourth PMOS transistor and a drain terminal of the fourth NMOS transistor.

17. The operational amplifier of claim 16 wherein:
the third PMOS transistor and the fourth PMOS transistor are coupled together via a source terminal of the third PMOS transistor and a source terminal of the fourth PMOS transistor; and
the third NMOS transistor and the fourth NMOS transistor are coupled together via a source terminal of the third NMOS transistor and a source terminal of the fourth NMOS transistor.

18. The operational amplifier of claim 17 wherein:
a gate terminal of the third PMOS transistor and a gate terminal of the third NMOS transistor are coupled to the first output of the input stage via the first capacitive coupling; and
a gate terminal of the fourth PMOS transistor and a gate terminal of the fourth NMOS transistor are coupled to the second output of the input stage via the second capacitive coupling.

19. The operational amplifier of claim 1 further comprising:
a biasing current circuit coupled to the first common-tail transistor.

20. The operational amplifier of claim 1 further comprising:
a common-mode feedback circuit coupled to the second common-tail transistor.
